(19) United States
(12) Patent Application Publication
(10) Pub. No.: US 2024/0321962 A1
(43) Pub. Date: Sep. 26, 2024

(54) ROUNDED NANORIBBONS WITH REGROWN CAPS

(71) Applicant: Intel Corporation, Santa Clara, CA (US)

(72) Inventors: Tao Chu, Portland, OR (US); Robin Chao, Portland, OR (US); Guowei Xu, Portland, OR (US); Feng Zhang, Hillsboro, OR (US); Minwoo Jang, Portland, OR (US)

(73) Assignee: Intel Corporation, Santa Clara, CA (US)

(21) Appl. No.: 18/187,965

(22) Filed: Mar. 22, 2023

(51) Int. Cl. H01L 29/06; H01L 21/8238; H01L 27/092; H01L 29/775

(52) U.S. Cl. CPC H01L 29/068; H01L 21/823807; H01L 27/092; H01L 29/0673; H01L 29/775; H01L 29/165; H01L 29/42392

(57) ABSTRACT

Described herein are nanoribbon-based transistor devices in which the nanoribbons have rounded cross-sections. The nanoribbons may include caps or outer layers of semiconductor channel material grown over an inner layer of semiconductor channel material. Different materials may be used for the outer layers of NMOS and PMOS transistors. In one example, an integrated circuit device includes NMOS transistors formed from or more nanoribbons with rounded cross-sections and an outer layer of silicon, and a PMOS transistors formed from or more nanoribbons with rounded cross-sections and an outer layer of silicon germanium.

### TECHNICAL FIELD

This disclosure relates generally to the field of integrated circuit (IC) structures and devices, and more specifically, to transistor devices with rounded nanoribbon channels having outer layers of deposited channel material.

### BACKGROUND

Gate all around (GAA) transistors, also referred to as surrounding-gate transistors, have a gate material that surrounds a channel region on all sides. GAA transistors may be nanoribbon-based or nanowire-based, and can also be referred to as a nanoribbon transistor or a nanowire transistor. In a nanoribbon transistor, a gate stack that may include one or more gate electrode materials and a gate dielectric may be provided around a portion of an elongated semiconductor structure called “nanoribbon”, forming the gate stack on all sides of the nanoribbon. A source region and a drain region can be provided on the opposite ends of the nanoribbon, on either side of the gate stack, forming, respectively, a source and a drain of such a transistor. GAA transistors, such as nanoribbon and nanowire transistors, may provide advantages compared to other transistors having a non-planar architecture, such as FinFETs.

With current nanoribbon processing techniques, the nanoribbons of channel material may have a non-ideal shape. For example, in a cross-section of a nanoribbon transistor through the gate, the nanoribbons may be thinner near the center of the ribbon and thicker towards the two sides. When the gate stack is grown around the nanoribbon, the shape of the nanoribbons can lead to gaps between adjacent nanoribbons where the gate electrode is not formed. These gaps can reduce device performance.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a nanoribbon-based transistor showing the source, gate, and drain, according to some embodiments of the present disclosure.

FIG. 1B is a cross-section across the gate regions of two nanoribbon-based transistors, according to some embodiments of the present disclosure.

FIG. 2A is a cross-section across a pair of adjacent nanoribbons, according to some embodiments of the present disclosure.

FIG. 2B is a cross-section of two stacks of nanoribbons through the plane CC′ of FIG. 2A, according to some embodiments of the present disclosure.

FIG. 3 is a cross-section of the stacks of nanoribbons etched around the gate regions, according to some embodiments of the present disclosure.

FIG. 4 is a cross-section illustrating the stacks of nanoribbons having been further etched, forming rounded shapes, according to some embodiments of the present disclosure.

FIG. 5 is a cross-section illustrating additional channel materials deposited over the rounded nanoribbons, according to some embodiments of the present disclosure.

FIG. 6 is a cross-section illustrating a cross-section of a stack of capped nanoribbons having stadium shapes, according to some embodiments of the present disclosure.

FIG. 7A is a cross-section illustrating gate material deposited around the nanoribbons, according to some embodiments of the present disclosure.

FIG. 7B is a cross-section through the plane EE′ of FIG. 7A, illustrating a nanoribbon-based transistor with capped nanoribbons, according to some embodiments of the present disclosure.

FIGS. 8A and 8B are top views of a wafer and dies that include one or more rounded nanoribbons with regrown caps in accordance with any of the embodiments disclosed herein.

FIG. 9 is a cross-sectional side view of an IC device that may include one or more rounded nanoribbons with regrown caps in accordance with any of the embodiments disclosed herein.

FIG. 10 is a cross-sectional side view of an IC device assembly that may include one or more rounded nanoribbons with regrown caps in accordance with any of the embodiments disclosed herein.

FIG. 11 is a block diagram of an example computing device that may include one or more rounded nanoribbons with regrown caps in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Described herein are IC devices that include nanoribbon-based transistors in which the nanoribbons have rounded cross-sections. The nanoribbons are etched to produce the rounded shape, and additional channel material is grown over the rounded nanoribbons, forming a cap or outer layer of channel material. The nanoribbon including the outer layer also has a rounded cross-section. An IC device may include both n-type metal-oxide-semiconductor (NMOS) transistors and p-type MOS (PMOS) transistors, e.g., alternating rows of NMOS and PMOS transistors. NMOS and PMOS logic typically use different groups of materials, e.g., silicon may be used as a n-type semiconductor channel, while silicon germanium may be used as a p-type semiconductor channel. Different outer layers may be selected for different material systems, e.g., a silicon outer layer may be used for an NMOS nanoribbon channel, while silicon germanium outer layer may be used for a PMOS channel. The cores of the nanoribbon channels may be the same for both material systems, e.g., the nanoribbon cores may be silicon.

Transistors typically include a gate stack coupled to a semiconductor channel. In a GAA, the semiconductor channel may include one or more nanoribbons, e.g., a set of nanoribbons stacked vertically over a support structure. A gate stack includes a gate electrode and a gate dielectric, with the gate dielectric formed between the gate electrode and the channel material. In a nanoribbon transistor, the gate dielectric is formed around each nanoribbon, and the gate electrode is formed over and around the gate dielectric, including in spaces between adjacent nanoribbons in the stack. If the nanoribbons have a non-ideal shape that is thinner in the center and thicker towards the ends, this can lead to gaps between adjacent nanoribbons where the gate electrode is not formed. These gaps can reduce device performance.

In some processes for fabricating nanoribbon-based transistors, a set of layers of alternating materials are formed, where one of the materials is the channel material (e.g., silicon), and the other material is a sacrificial material that is removed and replaced with the gate dielectric and gate electrode. For example, the sacrificial material may be silicon germanium, which enables layered epitaxial growth with the silicon channel material. Some portion of the sacrificial material is often left behind on or in the channel after the etching process to remove the sacrificial material. In particular, some of the sacrificial material (e.g., some of the germanium) may diffuse into the silicon, making it difficult to remove. For NMOS devices in particular, residual germanium can reduce device performance, e.g., by causing columbic scattering.

The residual material is typically present at or close to the surface of the channel, with very little residual material diffusing into the inner portion of the nanoribbon. As described herein, after the sacrificial material is removed, the remaining nanoribbons are further etched, to remove an outer layer of the nanoribbon channels. The etching removes some or all of the residual sacrificial material, e.g., the residual germanium. The etching process results in the nanoribbons having a rounded shape in their cross sections, with the ends being rounded, and the nanoribbons being tallest near their midpoints. For example, the nanoribbons may have an oval shape that curves along the top and bottom of the cross-section, or a stadium shape that is flatter along the tops and bottoms, but rounded at the ends.

After the nanoribbon channels are etched, additional channel material is grown or deposited over the nanoribbons, forming a cap or an outer layer, as described above. The outer layer follows the rounded shape of the etched nanoribbons. The rounded shape enables the gate dielectric and gate electrode materials to be deposited in the spaces between the nanoribbons, so that air pockets do not form within the gate electrode.

Different channel materials may be deposited for NMOS and PMOS devices. For example, silicon may be deposited for the NMOS devices, while a mixture of silicon and germanium deposited for the PMOS devices. The additional of germanium in the PMOS devices may provide improved performance than if only silicon is used as the channel.

The rounded nanoribbon channels described herein may be implemented in one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

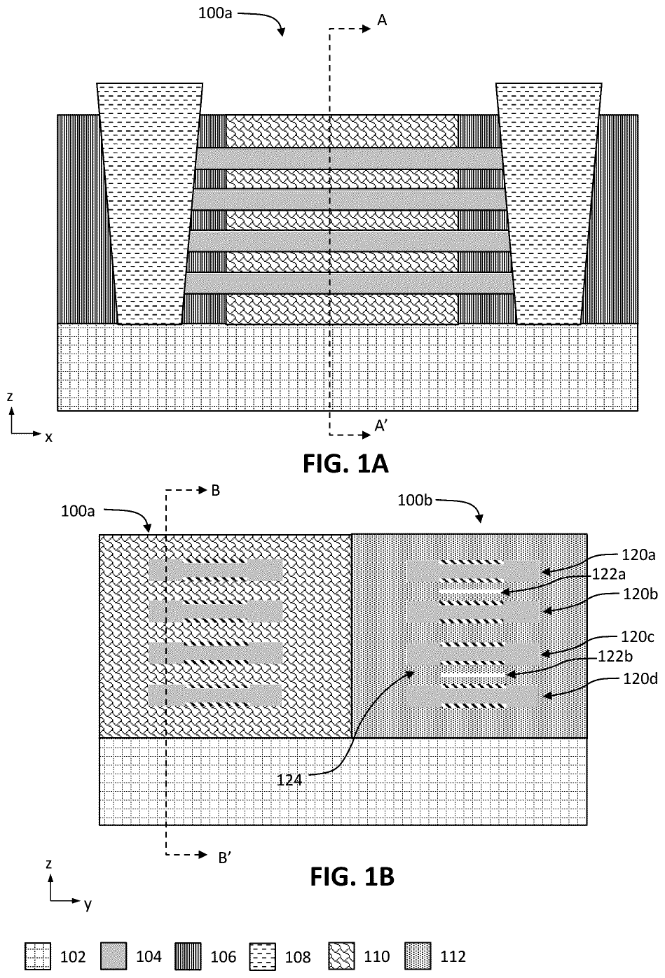

For convenience, if a collection of drawings designated with different letters are present, e.g., FIGS. 1A-1B, such a collection may be referred to herein without the letters, e.g., as “FIG. 1.”

Example Nanoribbon Transistor with Residual Sacrificial Material

FIGS. 1A-1B illustrate a nanoribbon-based transistor in which residue from a sacrificial material remains on the nanoribbon channels, which may lead to defects in the transistor. FIG. 1A is a cross-section across a transistor 100a showing the source, gate, and drain. FIG. 1B is a cross-section across the gate regions of two adjacent nanoribbon-based transistors 100a and 100b. FIG. 1B is a cross-section through the plane AA′ in FIG. 1A, and FIG. 1A is a cross-section through the plane BB′ in FIG. 1B.

A number of elements referred to in the description of FIGS. 1A and 1B with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) contact 108, a first gate electrode 110, a second gate electrode 112, and a residual material 114.

The transistors 100a and 100b, referred to jointly as transistors 100 or individually as a transistor 100, are formed over the support structure 102. Each transistor 100 includes a channel material 104 formed into four nanoribbons stacked on top of each other. For example, the transistor 100b includes nanoribbons 120a, 120b, 120c, and 120d. Each nanoribbon is at a different height in the z-direction in the orientation shown in FIG. 1. The transistors 100a and 100b each have four nanoribbons at the same or similar heights. The channel material 104 is a semiconductor, such as silicon. S/D contacts 108 are formed around either end of the nanoribbon channels, as illustrated in FIG. 1A.

A central portion of each of the nanoribbon channels is surrounded by a gate electrode 110 or 112. The gate electrodes 110 and 112 may be different materials suited for different materials systems, e.g., n-type and p-type. In this example, the transistor 100a is an NMOS transistor, and the transistor 100b is a PMOS transistor. Accordingly, the channel material 104 in the transistor 100a may have an n-type dopant, and the channel material 104 in the transistor 100b may have a p-type dopant. Further, the first gate electrode 110 may be an n-type work function metal, while the second gate electrode 112 may be a p-type work function metal. A gate dielectric, not specifically shown, may surround the nanoribbon channels under the gate electrodes 110 and 112. Regions of the nanoribbon channels not surrounded by the gate electrode 110 or 112 or by the S/D contacts 108 are filled in with a dielectric material 106.

FIG. 1B illustrates that a residual material 114 is on the outer surface of the channel material 104, e.g., along the top and bottom surfaces of the nanoribbons 120. As described above, the nanoribbons 120 may be formed by fabricating a set of layers of alternating materials, e.g., alternating layers of silicon (as the channel material 104) and silicon germanium. The silicon germanium is a sacrificial material that is etched away, leaving the nanoribbon channels. However, the etching process does not remove all of the germanium, leaving the residual material 114. In this example, some of the residual material 114 (e.g., some of the germanium) diffused into the channel material 104, in a central portion of the nanoribbons 120. Having residual material 114 in the channel material 104 can reduce device performance of the NMOS devices.

Furthermore, in some cases, some of the diffused germanium is removed from the central portion of the nanoribbon, which can alter the shape of the nanoribbons 120. In particular, removing material from the central part can result in a dog bone or barbell type shape in the y-z cross section, with wider ends and a pinched mid-section. This shape can result in unfilled pockets between nanoribbon channels, e.g., the pocket 122a between the nanoribbons 120a and 120b, and the pocket 122b between the nanoribbons 120c and 120d. When layers of gate dielectric and gate electrode material are deposited, the electrode material may close an area between adjacent nanoribbons so that the electrode material cannot be fully deposited between the nanoribbons. For example, the area 124 may be closed before the pocket 122b is filled, preventing material for forming the gate electrode 112 between the nanoribbons 120c and 120d from reaching the pocket 122b.

### Example Nanoribbon Stacks

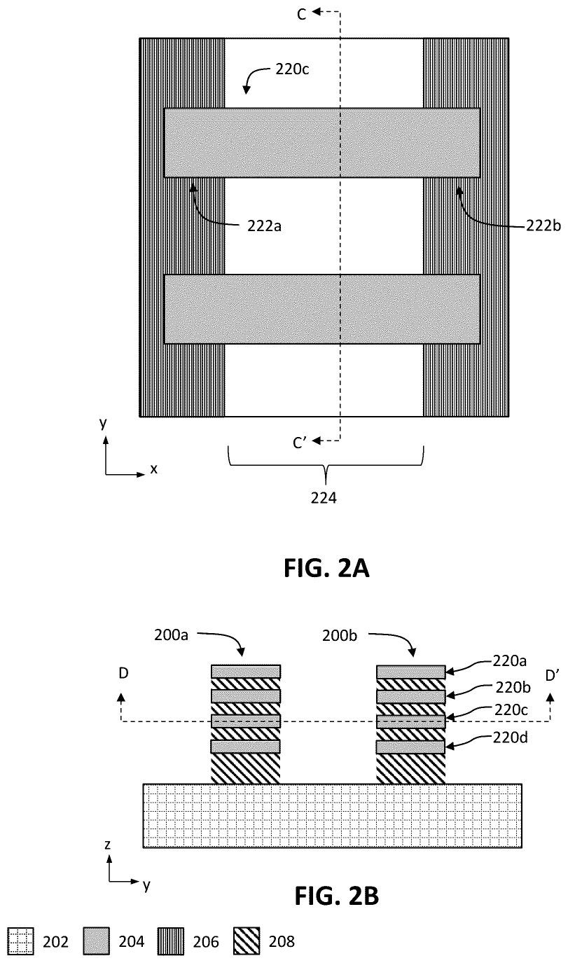

FIGS. 2A and 2B illustrate two stacks of nanoribbons for forming a pair of transistors. FIG. 2A is a cross-section across a pair of nanoribbons in adjacent stacks. FIG. 2B is a cross-section of the two stacks of nanoribbons through the plane CC′ of FIG. 2A. The plane DD′ of FIG. 2B is shown in FIG. 2A.

A number of elements referred to in the description of FIGS. 2-7 with reference numerals are illustrated in these figures with different patterns, with a legend showing the correspondence between the reference numerals and patterns being provided at the bottom or side of each drawing page containing FIGS. 2-7. For example, the legend in FIG. 2 illustrates that FIG. 2 uses different patterns to show a support structure 202, a channel material 204, a dielectric material 206, and a sacrificial material 208.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

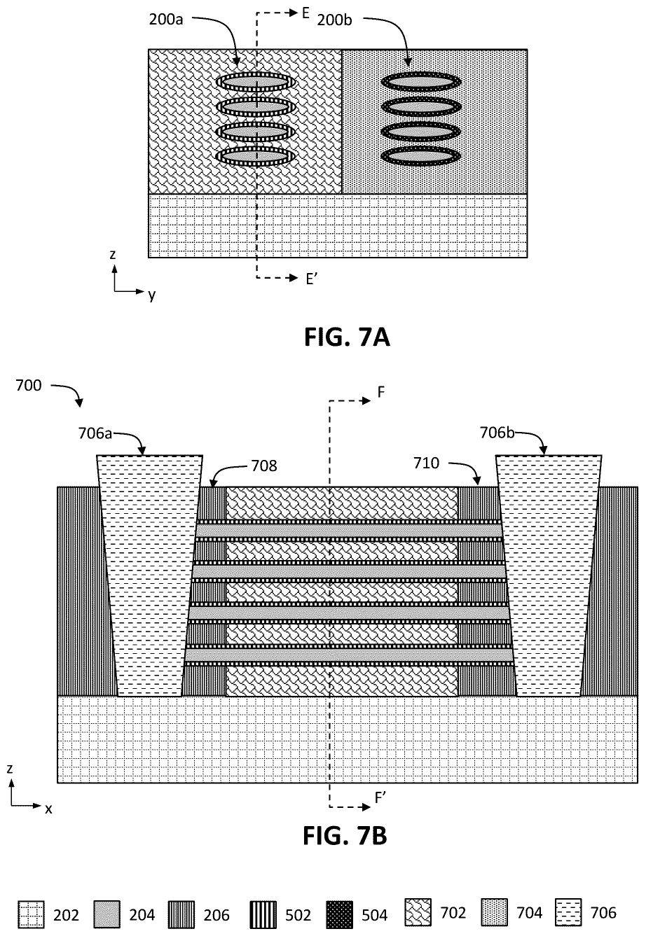

In general, implementations of the present disclosure may be formed or carried out on a support structure 202, such as a semiconductor substrate composed of semiconductor material systems including, for example, N-type or P-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. Although a few examples of materials from which the substrate may be formed are described here, any material that may serve as a foundation upon which a semiconductor device may be built falls within the spirit and scope of the present disclosure. In various embodiments the support structure 202 may include any such substrate that provides a suitable surface for providing the nanoribbon transistors described herein, e.g., the transistors 700a and 700b illustrated in FIG. 7.

Stacks of channel material 204 are formed over the support structure 202. To form nanoribbon channels, alternating layers of the channel material 204 and a sacrificial material 208 are deposited over the support structure 202. The channel material 204 and sacrificial materials 208 include different materials. For example, the channel material 204 is silicon, while the sacrificial material 208 is a mixture of silicon and germanium. The sacrificial material 208 may be chosen to have a similar crystal structure to the channel material 204, so that monocrystalline layers of the channel material 204 (or substantially monocrystalline layers, e.g., with a grain size of at least 5 nanometers, at least 20 nanometers, at least 50 nanometers, or at least 100 nanometers) and monocrystalline layers of the sacrificial material 208 (or substantially monocrystalline layers) may be formed over each other. In different embodiments, the channel material 204 and/or the sacrificial material 208 may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide III compound, where arsenic III is in combination with another element such as boron, aluminum, gallium, or indium), or any group III-V material (i.e., materials from groups III and V of the periodic system of elements).

More generally, the channel material 204 may be composed of semiconductor material systems including, for example, N-type or P-type materials systems. In other embodiments, the channel material 204 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 204 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

FIG. 2 illustrates the nanoribbon channel material 204 after stacks have been etched to form individuated channel regions. For example, rows may be patterned using photolithography, and portions of the alternating layers are removed, leaving the stacks 200a and 200b illustrated in FIG. 2B.

In the example shown in FIG. 2B, the channel material 204 is formed into four nanoribbons stacked on top of each other. For example, the stack 200b includes nanoribbons 220a, 220b, 220c, and 220d. Each nanoribbon 220 is at a different height in the z-direction in the orientation shown in FIG. 2B. The stacks 200a and 200b each have four nanoribbons. In other embodiments, the stacks 200a and 200b, and transistors formed from the nanoribbon stacks, may each have fewer nanoribbons (e.g., one, two, or three nanoribbons), or more than four nanoribbons (e.g., five nanoribbons, six nanoribbons, etc.). The sacrificial material 208 is below the lowest nanoribbon 220d (i.e., between the support structure 202 and the nanoribbon 220d) and between adjacent nanoribbons (e.g., between nanoribbon 220d and 220c, between nanoribbon 220c and 220b, etc.).

The nanoribbons 220 each have an elongated structure that extends over the support structure 202. Each nanoribbon 220 extends primarily in the x-direction in the coordinate system used in FIGS. 2-7. The direction in which the nanoribbons 220 extend is parallel to the support structure 202.

As illustrated in FIG. 2A, a dielectric material 206 is formed at either end of the nanoribbon channels, e.g., the ends 222a and 222b of the nanoribbon 220c. The dielectric material 206 may be a low-k or high-k dielectric including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials 206 include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

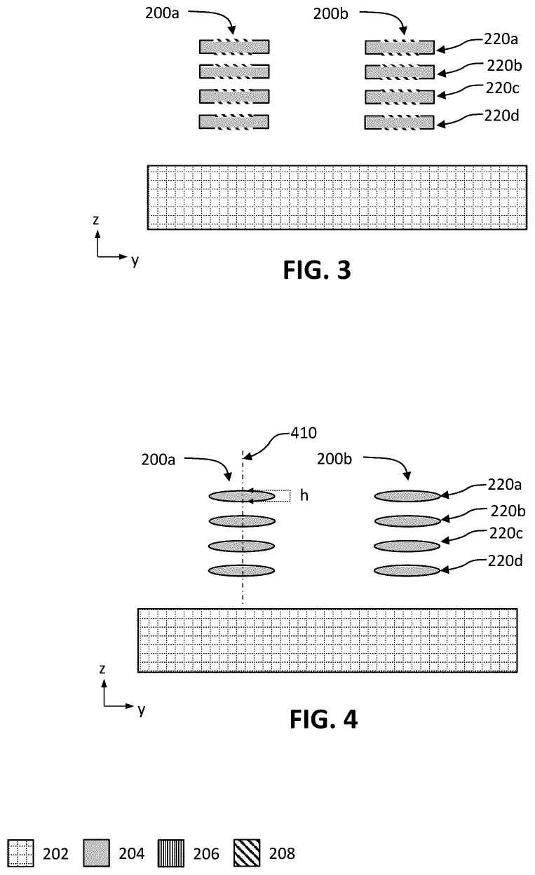

At the stage illustrated in FIG. 2, the layers of channel material 204 are supported by the alternating layers of sacrificial material 208. As illustrated in FIG. 3, the sacrificial material 208 is removed, leaving the nanoribbons 220 “floating.” After the sacrificial material 208 is removed, the nanoribbons 220 are supported on either end and held in their respective positions by the dielectric material 206.

As illustrated in FIGS. 1A and 1n FIG. 7B, in a finished transistor, a S/D contact is formed around the ends of the nanoribbon channels, e.g., around the ends 222a and 222b. The S/D contacts (not illustrated in FIG. 2) may replace a portion of the dielectric material 206. The S/D contacts may be fabricated at any point of the transistor fabrication process. A region between the dielectric material 206, labelled 224 in FIG. 2A, is a gate region of the transistor. A gate electrode is formed in some or all of the region 224, as illustrated in FIG. 7. The cross-section in FIG. 2B illustrates is a cross-section through the gate region, i.e., a region of the nanoribbons 220 around which the gate is formed.

### Example Process for Etching and Capping the Nanoribbons

FIGS. 3-5 illustrate a process for etching and capping the nanoribbons 220. This process involves releasing the nanoribbons 220, etching a portion of the channel material 204 from the nanoribbons 220, and capping or regrowing channel material over the etched nanoribbons 220.

FIG. 3 is a cross-section of stacks of released nanoribbons around the gate regions, according to some embodiments of the present disclosure. In FIG. 3, the sacrificial material 208 has been etched, leaving the nanoribbons 220 floating between the ends in the dielectric material 206, as described above. The sacrificial material 208 may be removed using an etching process, such as dry etch, wet etch, or a combination. An etchant material used to remove the sacrificial material 208 is selective to the channel material 204, i.e., the etchant removes the sacrificial material 208 but does not remove the channel material 204. This process may be referred to as nanoribbon release.

After the nanoribbon release, some portion of the sacrificial material 208 is left behind on or in the channel material 204. For example, some of the sacrificial material 208 (e.g., some germanium atoms) may have diffused into the channel material 204 (e.g., a silicon channel). The etching process does not remove the diffused sacrificial material 208. As another example, due to the geometry of the nanoribbons, the etchant may have a more difficult time reaching the central portion of the nanoribbons (in the y-z cross section) than the outer edges of the nanoribbons, leaving an outer layer of the sacrificial material 208 in the central portion of the nanoribbons, as illustrated in FIG. 3. As noted above, the residual sacrificial material 208 may reduce device performance. For example, for NMOS devices having a silicon channel, residual germanium can reduce device performance, e.g., by causing columbic scattering.

FIG. 4 is a cross-section illustrating the stacks of nanoribbons having been further etched, forming rounded shapes, according to some embodiments of the present disclosure. The rounded shapes are observed in a cross-section through the gate portions of the nanoribbons 220; this cross-section (e.g., the y-z cross-section in the example coordinate system) is perpendicular to the direction in which the nanoribbons 220 primarily extend (e.g., the x-direction in the example coordinate system). Any etching process, e.g., wet etching and/or dry etching, may be used to etch the nanoribbons 220. The etchant is selected to remove the channel material 204, and the process is tuned to remove an outer layer of the channel material 204, while leaving a portion of the channel material 204 behind. As noted above, the residual sacrificial material 208 is at or near the surface of the channel, so etching the nanoribbons 220 further removes most or all of the residual sacrificial material 208.

The etching reduces the overall heights of the nanoribbons 220, e.g., to a height h illustrated in FIG. 4. The height h is a height along a central axis 410 (also referred to as a midline 410) of the nanoribbons 220, where the central axis or midline 410 extends through each of the nanoribbons 220 in a given nanoribbon stack 200 in a direction perpendicular to the support structure 202. The height h may be in the range of, e.g., 0.1 nanometer to 5 nanometers. In some examples, the height h may be less than 2 nanometers (e.g., 0.3 to 2 nanometers), or less than 1 nanometers (e.g., between 0.5 and 1 nanometers).

Furthermore, the etching produces rounded edges in the cross-section of the nanoribbons 220 through the gate portion, as illustrated in FIG. 4. In the example shown in FIG. 4, the cross-section of the nanoribbons 220 has an oval shape. In other embodiments, the cross-section of the nanoribbons 220 may have a different shape, such as a stadium shape, or a shape between an oval and stadium shape. An example of nanoribbons with a stadium shape is shown in FIG. 6.

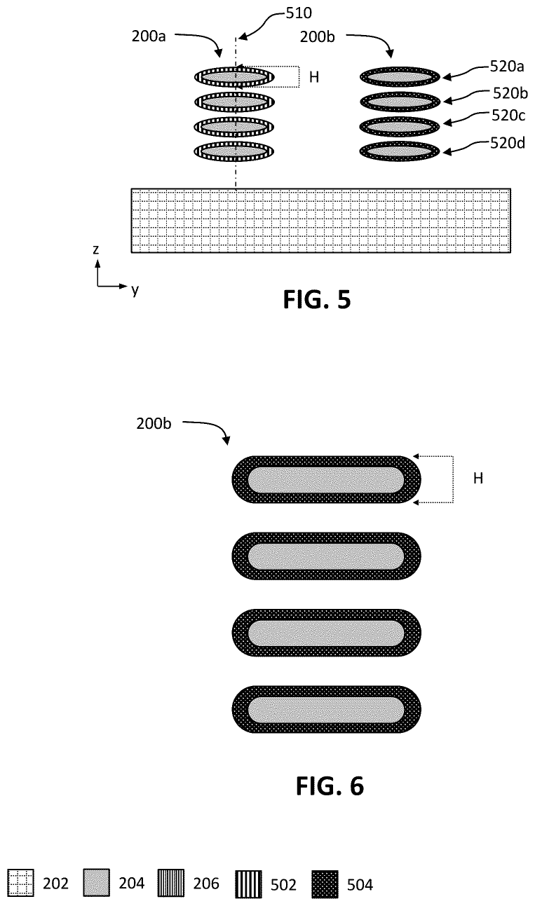

FIG. 5 is a cross-section illustrating additional channel materials deposited over the rounded nanoribbons, according to some embodiments of the present disclosure. After the nanoribbons 220 are etched to form the rounded shape shown in FIG. 4, additional channel material is grown or deposited over the nanoribbons 220, forming a cap or an outer layer. The channel material 204 may be referred to as an inner channel material or core material, and the inner portion of the capped nanoribbons may be referred to as a core. The nanoribbons 220 with the caps or outer layers may be referred to as capped nanoribbons 520.

In some embodiments, different channel materials are deposited to form different device types, e.g., for NMOS and PMOS devices. For example, the nanoribbon stack 200a may be used to form an NMOS device, while the nanoribbon stack 200b is used to form a PMOS device. Thus, a first outer channel material 502 is deposited around the nanoribbons in the stack 200a, and a second outer channel material 504 is deposited around the nanoribbons in the stack 200b. The outer channel materials 502 and 504 may each have a thickness below 3 nanometers or below 5 nanometers. In some embodiments, the outer channel materials 502 and 504 have thicknesses in a range of, e.g., 0.1 nanometers to 3 nanometers. In some examples, the thickness of the outer channel materials 502 and 504 may be between 0.5 nanometers and 1 nanometer, or between 1 nanometers and 2 nanometers. In some embodiments, the outer channel materials 502 and 504 may have different thicknesses from each other.

The outer channel materials 502 and 504 may also be different or distinguishable from the channel material 204. For example, for the NMOS device, the channel material 204 may be monocrystalline silicon (e.g., silicon having a grain size of at least 10 nanometers, at least 20 nanometers, or at least 50 nanometers), while the outer channel material 502 is polycrystalline (e.g., silicon having a grain size of less than 20 nanometers, less than 10 nanometers, or less than 5 nanometers) or amorphous silicon. In some embodiments, the outer channel material 502 is also monocrystalline, but a grain boundary is observable (e.g., in a SEM or TEM image) between the channel material 204 and the outer channel material 502.

For a PMOS device, the channel material 204 may be silicon, e.g., monocrystalline silicon, as described above. The outer channel material 504 may include germanium, e.g., silicon germanium. The silicon germanium may be a germanium alloy that includes at least 5%, at least 10%, or at least 20% germanium. For example, the silicon germanium may include between 20-60% germanium, and between 40-80% silicon.

The outer layers of the outer channel materials 502 and 504 follow the rounded shapes of the etched nanoribbons. In the example shown in FIG. 5, the capped nanoribbons 520 have a height H. The height H is a height along a central axis 510 (also referred to as a midline 510) of the capped nanoribbons 520, where the central axis or midline 510 extends through each of the capped nanoribbons 520 in a given nanoribbon stack 200 in a direction perpendicular to the support structure 202. The height H may be in the range of, e.g., 1 nanometer to 10 nanometers. In some embodiments, the height H is below 5 nanometers. For example, the height H may be between 1 nanometer and 3 nanometers, or between 3 nanometers and 5 nanometers.

If different outer channel materials 502 and 504 are used for NMOS and PMOS channels, a first processing step or sequence may be used to deposit a first outer channel material 502 around one portion of the nanoribbon stacks, and a second processing step or sequence may be used to deposit a second outer channel material 504 around another portion of the nanoribbon stacks. For example, the stack 200b may be blocked (e.g., using a hard mask) while the first outer channel material 502 is deposited, and the stack 200a may be blocked (e.g., using a second hard mask) while the second outer channel material 504 is deposited.

FIG. 6 illustrates an alternate embodiment of the nanoribbon stack 200b. In this embodiment, the nanoribbon core and the capped nanoribbons have a stadium-shaped cross-section. A stadium shape is flat on the top and bottom with two shorter, semi-circular sides. The stadium shape shown in FIG. 6 has the height H along a central axis; the height H is the height of the shape along the lengths of the flat top and bottom. While FIG. 5 illustrates an ideal oval shape, and FIG. 6 illustrates an ideal stadium shape, in practice, the capped nanoribbon cross-section may fall somewhere between a stadium and an oval, and the cross-section may have some irregularity.

Example Capped Nanoribbon Transistors with Rounded Cross-Sections

FIGS. 7A and 7B illustrate a pair of transistors formed around the capped nanoribbons 520 shown in FIG. 5. A similar pair of transistors may be formed around the stadium-shaped capped nanoribbons illustrated in FIG. 6.

FIG. 7A is a cross-section illustrating gate material deposited around the nanoribbons, according to some embodiments of the present disclosure. FIG. 7B is a cross-section through the plane EE′ of FIG. 7A, illustrating one of the nanoribbon-based transistors with capped nanoribbons. Turning first to FIG. 7A, a first gate electrode 702 is deposited around the first stack 200a of capped nanoribbons, and a second gate electrode 704 is deposited around the second stack 200b of capped nanoribbons. While not specifically shown, a gate dielectric may be deposited around each of the capped nanoribbons, surrounding each of the capped nanoribbons, and the gate electrodes 702 and 704 may be deposited around the gate dielectric. The rounded shape of the capped nanoribbons enables the gate dielectric and gate electrodes 702 and 704 to be deposited in the spaces between the nanoribbons, so that air pockets do not form within the gate electrodes.

The first gate electrode 702 and second gate electrode 704 may be different electrode materials. For example, the first gate electrode 702 may be a metal having an n-type work function, while the second gate electrode 704 may be a metal having a p-type work function. For a PMOS transistor, the gate electrode 704 may include, but is not limited to, ruthenium, palladium, platinum, cobalt, nickel, and conductive metal oxides (e.g., ruthenium oxide). For an NMOS transistor, the gate electrode 702 may include, but is not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). Other materials that may be used include titanium nitride, tantalum nitride, hafnium nitride, tungsten, iridium, copper, or degenerately doped poly-silicon. In some embodiments, one or both of the gate electrodes 702 or 704 may consist of a stack of two or more metal layers, where one or more metal layers are work function metal layers and at least one metal layer is a fill metal layer.

A first processing step or sequence may be used to deposit the first gate electrode 702, and a second processing step or sequence may be used to deposit the second gate electrode 704. For example, the stack 200b may be blocked (e.g., using a hard mask) while the first gate electrode 702 is deposited, and the stack 200a may be blocked (e.g., using a second hard mask) while the second gate electrode 704 is deposited.

Turning to FIG. 7B, a cross-section of a transistor 700 is illustrated. The transistor 700 includes a first S/D contact 706a, a second S/D contact 706b, and a channel region formed form the capped nanoribbons in the stack 200a, i.e., the channel material 204 and the first outer channel material 502 in this example. The first gate electrode 702 is around and between the capped nanoribbons. A cross-section of a transistor formed by the stack 200b has a similar appearance, with the second outer channel material 504 in place of the first outer channel material 502, and the second gate electrode 704 in place of the first gate electrode 702.

The S/D contacts 706a and 706b are formed around opposite ends of the nanoribbon channels. The S/D contacts 706 may be formed from one or more layers of metal and/or metal alloys. The S/D contacts 706 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the S/D contacts 706 may include one or more electrically conductive alloys, oxides, or carbides of one or more metals. In some embodiments, the S/D contacts 706 may include a doped semiconductor, such as silicon or another semiconductor doped with an N-type dopant or a P-type dopant. Metals may provide higher conductivity, while doped semiconductors may be easier to pattern during fabrication. In some embodiments, the S/D contacts 706 may include both a semiconductor and a metal, e.g., an atomic layer deposition (ALD)-deposited doped oxide semiconductor followed by metal.

The transistor 700 is surrounded by the dielectric material 206, which electrically isolates the transistor 700 from other transistors. In addition, two dielectric region 708 and 710 electrically isolate the first gate electrode 702 from the S/D contacts 706a and 706b, respectively. While one dielectric material 206 is shown in FIG. 7B, different regions or layers of dielectric material may be used in or around different parts of the transistor 700.

### Example Devices

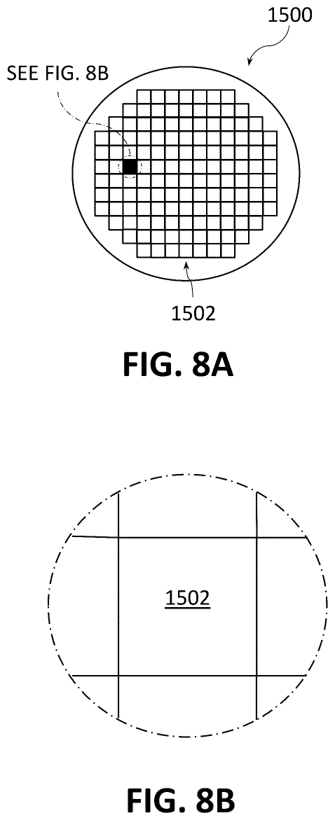

The transistor devices with rounded nanoribbons with regrown caps disclosed herein may be included in any suitable electronic device. FIGS. 8-11 illustrate various examples of apparatuses that may include the transistor devices with rounded nanoribbons with regrown caps disclosed herein.

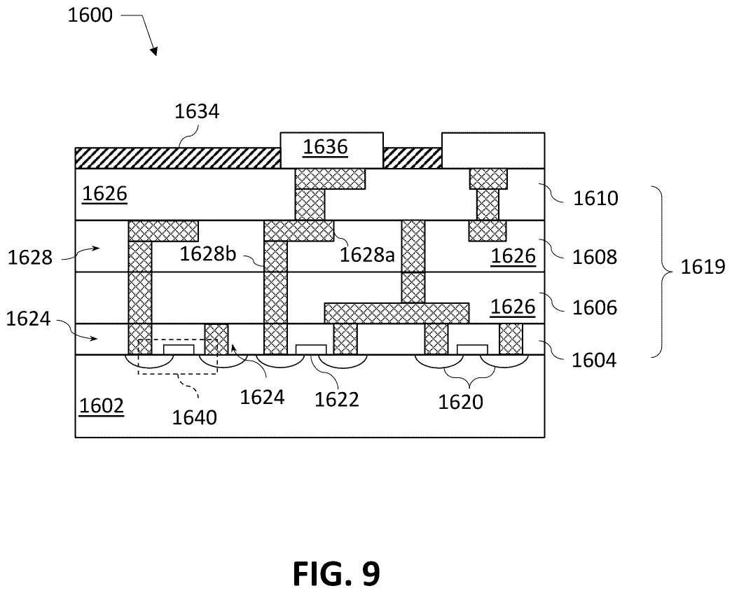

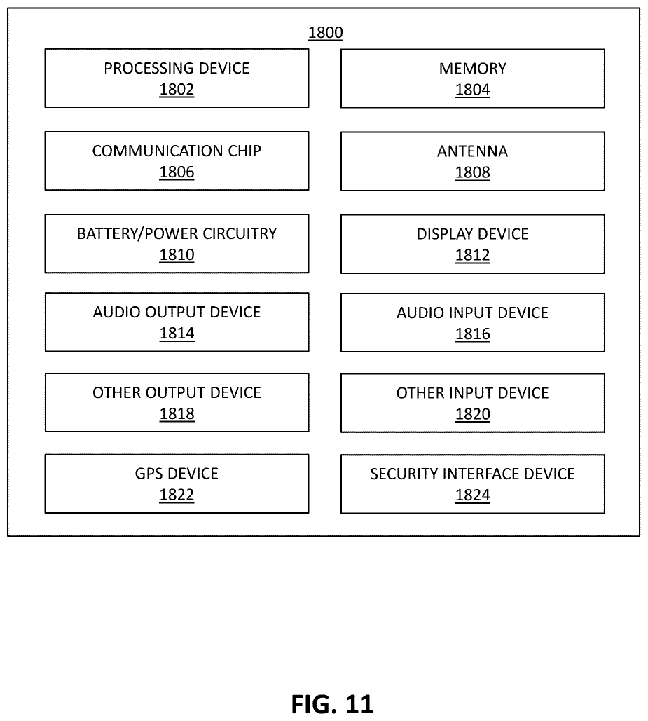

FIGS. 8A and 8B are top views of a wafer and dies that include one or more IC structures including rounded nanoribbons with regrown caps in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIG. 1, 2, or 4-6, or any further embodiments of the IC structures described herein). After the fabrication of the semiconductor product is complete (e.g., after manufacture of one or more IC structures with one or more transistor devices with rounded nanoribbons with regrown caps as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more rounded nanoribbons with regrown caps as disclosed herein may take the form of the wafer 1500 (e.g., not singulated) or the form of the die 1502 (e.g., singulated). The die 1502 may include one or more transistors (e.g., one or more of the transistors 1640 of FIG. 9, discussed below) and/or supporting circuitry to route electrical signals to the transistors, as well as any other IC components (e.g., one or more transistor devices including rounded nanoribbons with regrown caps). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 9 is a cross-sectional side view of an IC device 1600 that may include one or more rounded nanoribbons with regrown caps in accordance with any of the embodiments disclosed herein. The IC device 1600 may be formed on a substrate 1602 (e.g., the wafer 1500 of FIG. 8A) and may be included in a die (e.g., the die 1502 of FIG. 8B). The substrate 1602 may be any substrate as described herein. The substrate 1602 may be part of a singulated die (e.g., the dies 1502 of FIG. 8B) or a wafer (e.g., the wafer 1500 of FIG. 8A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more rounded nanoribbons with regrown caps at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 9. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 9. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

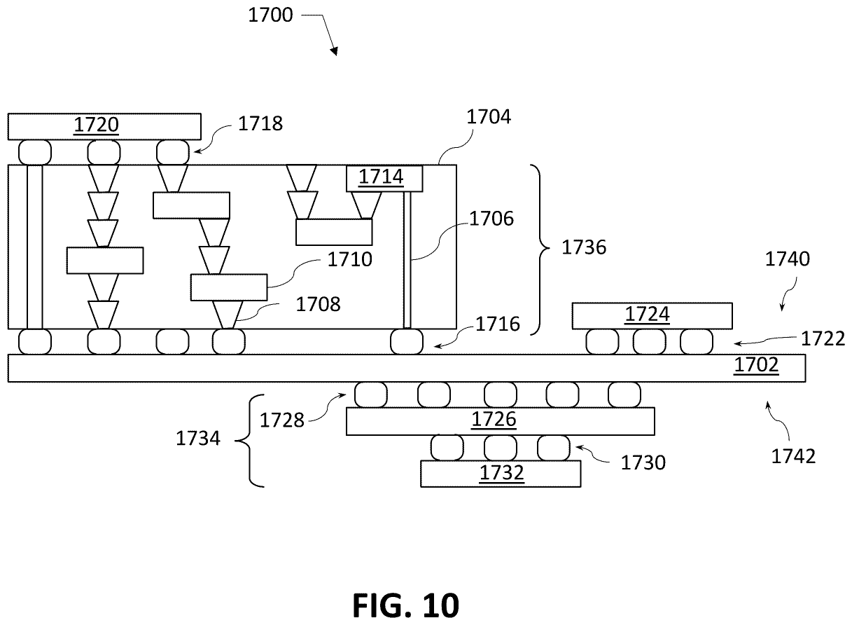

FIG. 10 is a cross-sectional side view of an IC device assembly 1700 that may include components having or being associated with (e.g., being electrically connected by means of) one or more rounded nanoribbons with regrown caps in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include any of the rounded nanoribbons with regrown caps disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8B), an IC device (e.g., the IC device 1600 of FIG. 9), or any other suitable component. In some embodiments, the IC package 1720 may include rounded nanoribbons with regrown caps, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example computing device 1800 that may include one or more components including one or more rounded nanoribbons with regrown caps in accordance with any of the embodiments disclosed herein. For example, any suitable ones of the components of the computing device 1800 may include a die (e.g., the die 1502 of FIG. 8B) having rounded nanoribbons with regrown caps as described herein. Any one or more of the components of the computing device 1800 may include, or be included in, an IC device 1600 (FIG. 9). Any one or more of the components of the computing device 1800 may include, or be included in, an IC device assembly 1700 (FIG. 10).

A number of components are illustrated in FIG. 11 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 11, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### SELECT EXAMPLES

The following paragraphs provide various examples of the embodiments disclosed herein.

Example 1 provides an IC device including a substrate; an elongated structure (e.g., a first nanoribbon) over the substrate, the elongated structure extending in a first direction parallel to the substrate, the elongated structure having a rounded shape in a cross-section perpendicular to the first direction, and the elongated structure including: a first semiconductor material (e.g., silicon); and a second semiconductor material (e.g., silicon for NMOS, SiGe for PMOS), the second semiconductor material surrounding the first semiconductor material in the cross-section.

Example 2 provides the IC device of example 1, where the first semiconductor material includes silicon, and the second semiconductor material includes a mixture of silicon and germanium.

Example 3 provides the IC device of example 2, where the second semiconductor material includes at least 20% germanium.

Example 4 provides the IC device of example 1, where the first semiconductor material includes silicon having a grain size of at least 5 nanometers.

Example 5 provides the IC device of example 4, where the second semiconductor material includes silicon having a grain size less than 5 nanometers.

Example 6 provides the IC device of example 1, where the rounded shape has a height in a direction parallel to the substrate and along a central axis of the elongated structure of less than 5 nanometers.

Example 7 provides the IC device of example 1, where the rounded shape of the cross-section of the elongated structure is a stadium shape.

Example 8 provides the IC device of example 1, where the rounded shape of the cross-section of the elongated structure is an oval.

Example 9 provides the IC device of example 1, further including a second elongated structure stacked below the elongated structure, the second elongated structure between the substrate and the elongated structure.

Example 10 provides the IC device of example 9, where the elongated structure and the second elongated structure are surrounded by a conductive material.

Example 11 provides an IC device including a support structure; a first plurality of elongated structures (e.g., NMOS nanoribbons) over the support structure, the first plurality of elongated structures extending in a first direction parallel to the support structure, the first plurality of elongated structures having a rounded shape in a cross-section perpendicular to the first direction; and a second plurality of elongated structures (e.g., PMOS nanoribbons) over the support structure, the second plurality of elongated structures extending in the first direction, the second plurality of elongated structures having the rounded shape in a cross-section perpendicular to the first direction; where an outer layer of the first plurality of elongated structures includes a first material, and an outer layer of the second plurality of elongated structures includes a second material different from the first material.

Example 12 provides the IC device of example 11, where the first material includes silicon, and the second material includes germanium.

Example 13 provides the IC device of example 12, where the second material further includes silicon.

Example 14 provides the IC device of example 11, further including a third material (e.g., an NMOS gate metal) surrounding the first plurality of elongated structures; and a fourth material (e.g., a PMOS gate metal) surrounding the second plurality of elongated structures, the third material different from the fourth material.

Example 15 provides the IC device of example 11, where each of the first plurality of elongated structure has a maximum height proximate to a midline of the first plurality of elongated structures, the midline extending through each of the first plurality of elongated structures.

Example 16 provides the IC device of example 15, where, in the cross-section, the rounded shapes of the first plurality of elongated structures taper towards ends of the first plurality of elongated structures, the ends on either side of the midline.

Example 17 provides IC device including a plurality of nanoribbons; a first source or drain at a first end of the plurality of nanoribbons; a second source or drain at a second end of the plurality of nanoribbons, the second end opposite the first end; and a gate formed around a portion of the plurality of nanoribbons, the gate between the first source or drain and the second source or drain; where, at a cross-section through the gate and through the plurality of nanoribbons, each of the plurality of nanoribbons has a rounded shape.

Example 18 provides the IC device of example 17, where each of the plurality of nanoribbons includes a core and an outer layer.

Example 19 provides the IC device of example 18, where, in the cross-section, the outer layer surrounds the core.

Example 20 provides the IC device of example 19, where the outer layer has a thickness between 1 nanometers and 3 nanometers.

Example 21 provides an IC package that includes an IC die, including one or more of the IC devices according to any one of the preceding examples. The IC package may also include a further component, coupled to the IC die.

Example 22 provides the IC package according to example 21, where the further component is one of a package substrate, a flexible substrate, or an interposer.

Example 23 provides the IC package according to examples 21 or 22, where the further component is coupled to the IC die via one or more first level interconnects.

Example 24 provides the IC package according to example 23, where the one or more first level interconnects include one or more solder bumps, solder posts, or bond wires.

Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).

Example 26 provides the computing device according to example 25, where the computing device is a wearable computing device (e.g., a smart watch) or hand-held computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
a substrate;
an elongated structure over the substrate, the elongated structure extending in a first direction parallel to the substrate, the elongated structure having a rounded shape in a cross-section perpendicular to the first direction, and the elongated structure comprising:
a first semiconductor material; and
a second semiconductor material, the second semiconductor material surrounding the first semiconductor material in the cross-section.

2. The IC device of claim 1, wherein the first semiconductor material comprises silicon, and the second semiconductor material comprises a mixture of silicon and germanium.

3. The IC device of claim 2, wherein the second semiconductor material comprises at least 20% germanium.

4. The IC device of claim 1, wherein the first semiconductor material comprises silicon having a grain size of at least 5 nanometers.

5. The IC device of claim 4, wherein the second semiconductor material comprises silicon having a grain size less than 5 nanometers.

6. The IC device of claim 1, wherein the rounded shape has a height in a direction parallel to the substrate and along a central axis of the elongated structure of less than 5 nanometers.

7. The IC device of claim 1, wherein the rounded shape of the cross-section of the elongated structure is a stadium shape.

8. The IC device of claim 1, wherein the rounded shape of the cross-section of the elongated structure is an oval.

9. The IC device of claim 1, further comprising a second elongated structure stacked below the elongated structure, the second elongated structure between the substrate and the elongated structure.

10. The IC device of claim 9, wherein the elongated structure and the second elongated structure are surrounded by a conductive material.

11. An integrated circuit (IC) device comprising:
a support structure;
a first plurality of elongated structures over the support structure, the first plurality of elongated structures extending in a first direction parallel to the support structure, the first plurality of elongated structures having a rounded shape in a cross-section perpendicular to the first direction; and
a second plurality of elongated structures over the support structure, the second plurality of elongated structures extending in the first direction, the second plurality of elongated structures having the rounded shape in a cross-section perpendicular to the first direction;
wherein an outer layer of the first plurality of elongated structures comprises a first material, and an outer layer of the second plurality of elongated structures comprises a second material different from the first material.

12. The IC device of claim 11, wherein the first material comprises silicon, and the second material comprises germanium.

13. The IC device of claim 12, wherein the second material further comprises silicon.

14. The IC device of claim 11, further comprising:
a third material surrounding the first plurality of elongated structures; and
a fourth material surrounding the second plurality of elongated structures, the third material different from the fourth material.

15. The IC device of claim 11, wherein each of the first plurality of elongated structure has a maximum height proximate to a midline of the first plurality of elongated structures, the midline extending through each of the first plurality of elongated structures.

16. The IC device of claim 15, wherein, in the cross-section, the rounded shapes of the first plurality of elongated structures taper towards ends of the first plurality of elongated structures, the ends on either side of the midline.

17. An integrated circuit (IC) device comprising:
a plurality of nanoribbons;
a first source or drain at a first end of the plurality of nanoribbons;
a second source or drain at a second end of the plurality of nanoribbons, the second end opposite the first end; and
a gate formed around a portion of the plurality of nanoribbons, the gate between the first source or drain and the second source or drain;
wherein, at a cross-section through the gate and through the plurality of nanoribbons, each of the plurality of nanoribbons has a rounded shape.

18. The IC device of claim 17, wherein each of the plurality of nanoribbons comprises a core and an outer layer.

19. The IC device of claim 18, wherein, in the cross-section, the outer layer surrounds the core.

20. The IC device of claim 19, wherein the outer layer has a thickness between 1 nanometers and 3 nanometers.
